(19) United States
(12) Patent Application Publication
(10) Pub. No.: US 2018/0158992 A1
(43) Pub. Date: Jun. 7, 2018

(54) LED MODULE

(71) Applicant: TRIDONIC JENNERSDORF GMBH, Jennersdorf (AT)

(72) Inventors: Robert HÖBER-NEUHOLD, Feldbach (AT); Clemens MAYER, Welten (AT); Peter PACHLER, Graz (AT); Georg PARTEDER, Gleisdorf (AT); Florian WIMMER, Payerbach (AT)

(73) Assignee: TRIDONIC JENNERSDORF GMBH, Jennersdorf (AT)

(21) Appl. No.: 15/580,218

(22) PCT Filed: May 20, 2016
(86) PCT No.: PCT/AT2016/050152

§ 371 Date: Dec. 6, 2017

(30) Foreign Application Priority Data
Jun. 15, 2015 (DE) 20 2015 103 126.2

(51) Int. Cl. H01L 33/50

(52) U.S. Cl. CPC H01L 33/50; F21Y 2115/10; H01L 2224/42

(57) ABSTRACT

The invention relates to a method for producing an LED module (1) and comprises at least the following steps:—providing at least one LED chip (4) on a substrate material (2), and—dispensing a not-cured (flowable/liquid) potting compound (3) on top of the LED chip (4), said potting compound (3) containing at least one type of luminescent particles and preferably a matrix material. During the step of dispensing, a predetermined potential is applied directly or indirectly to at least one LED chip (4).

### FIELD OF THE INVENTION

The present invention relates to an LED module (light-emitting diode module) for emitting mixed light, preferably white light. Furthermore, the present invention relates to a lighting device comprising at least one such LED module.

### BACKGROUND

LED modules suitable for emitting mixed light, in particular white light, are known from the prior art. The mixed light arises as a result of a spectrum of one or more LEDs being mixed with the emission spectrum of at least one phosphor excited by the LED(s), wherein the emission spectrum of at least one phosphor differs from the spectrum of at least one LED.

Said LED modules generally comprise at least one light-emitting light field, which is usually formed by a plurality of LEDs being coated with a potting compound or other covering that contains at least one phosphor.

The document DE 20 2014 103 029 U1 discloses for example LED modules having light fields which comprise differently embodied areal regions for emitting different light spectra. Said areal regions are separated from the further areal regions here in each case by dams or partitions. LED chips or LED strings are arranged in the regions separated in each case by the dams. During production, said areal regions are covered with a potting compound containing phosphor particles. After the areal regions have been filled with the potting compound, said phosphor particles sink in the potting compound and deposit on and around the LED chips. The potting compound or the potting compounds here can comprise different phosphor particles or different phosphor particle mixtures, such that the areal regions can emit corresponding light spectra in order that, for example, a desired mixed light can be provided by the LED module. Such a production method is also referred to as a so-called “dam-and-fill” method.

It has now been found that, particularly in the case of such LED modules produced by a “dam-and-fill” method, a certain light emission that is inhomogeneous over the emission angle can occur, particularly if a comparatively high proportion of phosphor particles were introduced into the potting compound, for example in order that a high luminance can be provided by the LED module. Furthermore, it was possible to ascertain such an inhomogeneous light emission generally in the case of LED modules in which a potting compound is applied in which phosphor particles can still move within the matrix material (for example on an epoxy or silicone basis).

In light of this prior art, it is an object of the present invention to provide an LED module and a lighting device with which a more homogeneous light emission can be provided, in particular even in the case of LED modules having a high phosphor particle density.

This object and other objects that are also mentioned or may be recognized by the person skilled in the art during the reading of the following description are achieved by the subject matter of the independent claims The dependent claims develop the central concept of the present invention in a particularly advantageous manner.

### SUMMARY

An LED module according to the invention is producible by a method comprising at least the following steps:

providing at least one LED chip on a carrier material,

dispensing a non-cured (flowable/liquid) potting compound above the

LED chip,

wherein the potting compound contains at least one type of phosphor particles and preferably a matrix material,

wherein a predetermined potential is applied to at least one LED chip directly or indirectly during the dispensing process.

In one preferred embodiment, the LED module is producible by a method wherein the carrier material is concomitantly formed by a module plate with preferably at least one dam which delimits at least one light field, wherein at least one LED chip is arranged within the light field.

One solution according to the invention for applying a predetermined potential to at least one LED chip may be that short-circuiting of the electrical terminals of the at least one LED chip is carried out while the phosphor particles sink in the liquid potting compound. Preferably, the electrical terminals of the at least one LED chip can additionally or alternatively be grounded, i.e. connected to a ground terminal, for example to a reference potential terminal.

By means of a short circuit of the electrical terminals of the LED chip or LED chips, at the terminals of an LED chip it is thus possible to apply the same potential for all terminals of an LED chip, as a result of which charge carriers possibly present and hence an indeterminate potential possibly present at one of the LED chips or parts thereof are reduced.

By connecting the terminals of an LED chip to ground, it is possible moreover to bring the potential of the LED chips to zero, and it is thus possible to avoid the existence of a potential difference with respect to the surroundings of the LED chip or parts of the dispensing device.

Applying a predetermined potential to at least one LED chip can for example also be carried out by applying an AC voltage to the electrical terminals of the at least one LED chip while the phosphor particles sink in the liquid potting compound. The voltage and the frequency of the AC voltage can be chosen in such a way that the phosphor particles sink substantially linearly in the liquid potting compound.

A further solution for achieving a more homogeneous distribution of the phosphor particles within the potting compound consists in an AC voltage being applied as a predetermined potential to the LED chip or LED chips and alternating electrical potentials thus being built up, such that a deflection of the positively charged phosphor particles can be avoided or substantially avoided. The voltage and the frequency of the AC voltage can be adapted here in a simple manner in such a way that the phosphor particles can sink in the still liquid potting compound substantially linearly, that is to say as far as possible without deflection and rectilinearly, and can thus be arranged homogeneously on and around the LED chip or the LED chips.

Applying a predetermined potential to at least one LED chip can for example also be carried out by applying a DC voltage to the electrical terminals of the at least one LED chip while the phosphor particles sink in the liquid potting compound, in order to deflect the phosphor particles at least partly in the direction of the LED chips.

By applying a DC voltage as a predetermined potential, it is possible for an electric field to be provided by the LED chip in a targeted manner, such that the sinking movement of the charged phosphor particles can be influenced in a targeted manner, for example in order to be able to guide the phosphor particles to the lateral regions of the LED chips in a targeted manner.

An LED module according to the invention is producible by a method comprising at least the following steps:

providing at least one LED chip on a carrier material,

dispensing a non-cured (flowable/liquid) potting compound above the LED chip,

wherein the potting compound contains at least one matrix material and at least one type of phosphor particles,

wherein, during the dispensing process, at least the region of the potting compound is shielded from light in the region of the excitation spectrum of the phosphor particles.

In the context of the present invention it was possible to establish that the inhomogeneous light emission discussed above is based on an inhomogeneous distribution of the phosphor particles within the potting compound, this inhomogeneity being the greatest in particular in the region of the LED chips. Moreover, it was possible to ascertain that this inhomogeneity is more pronounced in the case of LED chips having a comparatively high phosphor particle density.

As a result of investigations, it was furthermore possible to establish that the phosphor particles are charged positively during the mixing process in the potting compound, and that on account of the ambient light and the photoelectric effect associated therewith the LED chips build up an electrical potential and hence an electric field within the electrodes. Said electric field between the electrodes of the LED chip leads to the deflection of the electrically positively charged phosphor particles during the sinking process and thus leads to an inhomogeneous distribution of the phosphor particles. The present invention now provides a number of solutions as to how said deflection of the phosphor particles during the sinking process within the potting compound can be reduced or avoided preferably by indirectly or directly applying a predetermined potential.

One solution can be provided by the LED chips being darkened at least during the sinking process, such that no or only a considerably reduced photoelectric effect occurs, such that no or a considerably reduced deflection of the positively charged phosphor particles occurs. Such a darkening is thus one form of indirectly applying a predetermined potential to the LED chips. Such a darkening can be carried out for example by only the LED chips being covered during the sinking process or by substantially the entire LED module being covered. This can be carried out for example by means of a dark or black film that is arranged on the LED chips or on the LED module after the potting compound has been dispensed. Such a darkening can also be provided by the LED module being arranged in a dark environment (for example in a dark room or in a darkened drying channel) at least during the sinking of the phosphor particles.

Furthermore, there is the possibility of the LED chips or the LED module not being completely darkened, but rather being darkened only in such a way that only or substantially only light which leads to no or only to a small photoelectric effect can impinge on the LED chips. In other words, the LED chips in this case are illuminated only with light that lies outside the (main) absorption spectrum of the LED chips. Such a quasi selective illumination can be provided by corresponding luminaires provided in the corresponding production regions. Furthermore, there is also the possibility of using a covering film that provides a corresponding filter function.

The abovementioned proposals for darkening the LED chips or the LED module can be implemented here only during the sinking process or else during the other production steps or even during the entire production process.

LED modules produced by the various solutions proposed here have a more homogeneous phosphor particle distribution in comparison with the known LED modules, such that a more homogeneous light emission arises as a result.

In one particularly preferred embodiment, the LED module is producible by a method comprising at least the following steps:

providing a module preferably with at least one dam which delimits at least one light field, wherein at least one LED chip is arranged within the light field;

dispensing a liquid potting compound onto the LED chip, wherein the potting compound comprises phosphor particles; and

darkening the at least one LED chip in such a way that at least in the absorption spectrum of the LED chip no light passes to the at least one LED chip at least during the sinking of the phosphor particles in the liquid potting compound.

The present invention is not restricted to LED modules that comprise dams, but rather relates generally to LED modules in which a potting compound is applied (dispensed) in which phosphor particles can still move within the matrix material (for example on an epoxy or silicone basis).

A further LED module according to the invention is produced according to a method comprising at least the following steps:

providing a module plate preferably with at least one dam which delimits at least one light field, wherein at least one LED chip is arranged within the light field;

dispensing a liquid potting compound onto the LED chip, wherein the potting compound comprises phosphor particles;

indirectly or directly applying a predetermined potential to the LED chips by arranging the LED module within a magnetic field while the phosphor particles sink in the liquid potting compound, wherein the alignment and the magnetic field strength of the magnetic fields are chosen in such a way that the phosphor particles sink substantially linearly in the liquid potting compound.

A further solution for achieving a more homogeneous distribution of the phosphor particles within the potting compound consists in arranging the LED module within a (compensation) magnetic field at least during the sinking of the phosphor particles. By means of such a magnetic field and thus applying a predetermined potential to the LED chips, it is possible to virtually compensate for the deflection forces that occur on account of the electrical potential between the electrodes of the LED chip or LED chips, such that the phosphor particles can sink substantially without deflection and can deposit around the LED chip. Depending on the charge of the phosphor particles and depending on the magnitude of the electrical potential between the electrodes of the LED chip, the alignment and the magnetic field strength of the magnetic field should be set accordingly in order to enable a substantially linear sinking of the phosphor particles.

A further LED module according to the invention is produced according to a method comprising at least the following steps:

providing a module plate preferably with at least one dam which delimits at least one light field, wherein at least one LED chip is arranged within the light field;

dispensing a liquid potting compound onto the LED chip, wherein the potting compound comprises phosphor particles;

wherein, at least during the sinking of the phosphor particles in the potting compound, the LED module is arranged obliquely with respect to the horizontal in such a way that the phosphor particles sink substantially linearly in the liquid potting compound.

A further solution for achieving a more homogeneous distribution of the phosphor particles within the potting compound consists in arranging the LED module obliquely with respect to the horizontal at least during the sinking of the phosphor particles, such that the deflection of the phosphor particles that occurs can be compensated for as far as possible by the gravitational force and the phosphor particles can in turn sink as rectilinearly as possible in the still liquid potting compound. Depending on the charge of the phosphor particles and depending on the magnitude of the electrical potential between the electrodes of the LED chip, the angle of the inclination of the LED module during the sinking of the phosphor particles should be adapted accordingly in order to enable a substantially linear sinking of the phosphor particles.

A further LED module according to the invention is produced according to a method comprising at least the following steps:

providing a module plate preferably with at least one dam which delimits at least one light field, wherein at least one LED chip is arranged within the light field;

dispensing a liquid potting compound onto the LED chip, wherein the potting compound comprises phosphor particles;

wherein, at least during the sinking of the phosphor particles in the potting compound, the LED module is accelerated in such a way that a distribution of the phosphor particles that is as homogeneous as possible is provided at least around the region of the at least one LED chip.

Such acceleration of the LED module makes it possible to generate a force opposite to the deflection on account of the positive charge of the phosphor particles and the electrical potential between the electrodes of the LED chip or LED chips, which force leads to a more homogeneous distribution of the phosphor particles.

Such an acceleration can be achieved for example by the LED module being moved in an oscillating manner during the sinking of the phosphor particles in the potting compound, by the LED module being moved continuously on a three-dimensional path during the sinking of the phosphor particles in the potting compound, or by the LED module being moved jerkily at least once during the sinking of the phosphor particles in the potting compound.

A further LED module according to the invention is produced according to a method comprising at least the following steps:

providing a module plate, preferably with at least one dam which delimits at least one light field, wherein at least one LED chip is arranged within the light field;

dispensing a liquid potting compound onto the LED chip, wherein the potting compound comprises phosphor particles;

wherein, after the sinking of the phosphor particles in the liquid potting compound, a directional flow is generated in order to provide a distribution of the phosphor particles that is as homogeneous as possible at least around the region of the at least one LED chip.

Such a directional flow can be generated for example by a stirring device arranged in the liquid potting compound, for example a microstirrer. By means of such a flow, the deflection effected during the sinking and the associated inhomogeneous distribution of the phosphor particles can be eliminated again.

A further LED module according to the invention is produced according to a method comprising at least the following steps:

providing a module plate preferably with at least one dam which delimits at least one light field, wherein at least one LED chip is arranged within the light field;

dispensing a liquid potting compound onto the LED chip, wherein the potting compound comprises phosphor particles;

wherein during the sinking of the phosphor particles in the liquid potting compound, the LED module is operated at intervals by directly applying a predetermined potential in such a way that the potting compound cures layer by layer on account of the light emission.

Such curing of the potting compound layer by layer during the sinking of the phosphor particles makes it possible to prevent a further deflection of the phosphor particles that otherwise occurs, and to achieve a more homogeneous phosphor particle distribution. In other words, as a result of applying at intervals a supply voltage for the operation of the LED module and the LED chips contained thereon and thus as a result of operating the LED module at intervals and as a result of the layer-by-layer curing of the potting compound that is brought about thereby, the phosphor particles are virtually frozen during sinking in a desired (as far as possible still not significantly deflected) position. However, the potting compound here need not cure completely, but rather need only become sufficiently solid that a further movement (deflection) of the phosphor particles in the cured layer is prevented or substantially prevented.

A further LED module according to the invention is produced according to a method comprising at least the following steps:

providing a module plate preferably with at least one dam which delimits at least one light field, wherein at least one LED chip is arranged within the light field;

sieving phosphor particles onto the at least one light field;

dispensing a liquid potting compound onto the LED chip.

By way of example, the phosphor particles here can be embedded into a liquid matrix prior to sieving, that is to say can be sieved virtually wet, or else can be sieved as (preferably dry) phosphor powder onto the at least one light field. By sieving the phosphor particles before filling the light field with liquid potting compound, it is possible to avoid the step of sinking of the phosphor particles and the associated deflection of the phosphor particles, such that a more homogeneous distribution of the phosphor particles at and around the LED chip or LED chips can be provided.

A further LED module according to the invention is produced according to a method comprising at least the following steps:

providing a module plate, preferably with at least one dam which delimits at least one light field, wherein at least one LED chip is arranged within the light field;

applying phosphor particles onto the at least one light field by means of a spray mist coating step;

dispensing a liquid potting compound onto the LED chip.

Instead of sieving the phosphor particles, a spray mist method is also suitable for providing a more homogeneous distribution of the phosphor particles at and around the LED chip or LED chips. Here too, the step of sinking of the phosphor particles can be avoided, such that here, too, a more homogeneous distribution of the phosphor particles can be provided.

A further LED module according to the invention comprises at least:

a module plate preferably with at least one dam which delimits at least one light field, wherein at least two linearly arranged LED strings each having a plurality of series-connected LED chips are provided within the light field; and wherein

the LED strings are arranged with alternating polarities in the at least one light field.

With the use of LED strings comprising a plurality of series-connected LED chips, the electrical potential correspondingly increases on account of the photoelectric effect. This effect can be at least reduced if the LED strings are arranged with alternating polarities in such a way that their electric fields at least partly cancel one another out. A predetermined potential, for example a DC voltage or an AC voltage, can preferably be applied directly or indirectly to the individual LED springs and thus the polarity of series-connected LED chips.

A further LED module according to the invention comprises at least:

a module plate preferably with at least one dam which delimits at least one light field, wherein a polarity of LED chips are provided within the light field; and wherein

the LED chips are arranged in alternating polarity with respect to one another in the at least one light field.

Furthermore, the deflection of the phosphor particles on account of the electric fields of the LED chips can be at least reduced if the LED chips are arranged in the light field with alternating polarities with respect to one another in such a way that their electric fields at least partly cancel one another out. Here, by way of example, a plurality of LED chips arranged in a row or a column can be arranged with alternating polarity in each case, such that their electric fields at least partly cancel one another out.

Preferably, the phosphor particles used in an LED module according to the invention are from inorganic phosphor particles, for example ZnS, ZnSe, CdS, CdSe, ZnTe, CdTe, (Ca₃Sc₂Si₃O₁₂: Ce₃₊), orthosilicates (BOSE), garnets (YAG: Ce³⁺, (YGd)AG:Ce³⁺, LuAg: Ce³⁺), oxides (CaScO₂: Eu²⁺), SiALONs [a-SiALON: Eu²⁺, b-SiALON: Eu²⁺), nitrides (La₃Si₆N₁₁: Ce³⁺, CaAlSiN₃: Ce³⁺), oxynitrides (SrSi₂N₂O₂: Eu²⁺, (Ca,Sr,Ba)Si₂N₂O₂: Eu²⁺). Generally, as phosphors use can be made of any substances/particles which are excitable by light that can be emitted by the LED chips used, and which thereupon emit a second light spectrum.

Advantageously, the potting compound used in an LED module according to the invention is a silicone- and/or epoxy-based potting compound which, in the spectral ranges that are important for the function, is preferably already completely transparent in the liquid state and preferably at least in the crosslinked state. The potting compound can furthermore comprise scattering particles for more homogeneous light intermixing.

Advantageously, the dam preferably used in the present invention or the dams used (if the LED module is intended to comprise a plurality of light fields) has/have a width as seen in plan view of between 50 μm and 2 mm, preferably between 100 μm and 1 mm, and particularly preferably between 300 μm and 800 μm. Such a dam or a dam structure here can either be formed directly on the module plate, for example by a suitable material being applied and cured (for example by a dispensing method), or firstly be produced as a separate component that is subsequently connected to the module plate.

The invention also relates to a method for producing an LED module, said method comprising at least the following steps:

providing at least one LED chip on a carrier material,

dispensing a non-cured (flowable/liquid) potting compound above the LED chip,

wherein the potting compound contains at least one type of phosphor particles and preferably a matrix material,

wherein a predetermined potential is applied to at least one LED chip directly or indirectly during the dispensing process.

Finally, the present invention relates to a lighting device comprising at least one of the LED modules described above.

### BRIEF DESCRIPTION OF THE DRAWINGS

A detailed description of the figures is given below, wherein:

FIG. 1 shows a schematic view of a first embodiment of an LED module according to the invention during the production process;

FIG. 2 shows a schematic view of a second embodiment of an LED module according to the invention during the production process;

FIG. 3 shows a schematic view of a third embodiment of an LED module according to the invention during the production process; and

FIG. 4 shows a schematic view of a fourth embodiment of an LED module according to the invention during the production process.

### DETAILED DESCRIPTION OF THE PREFERRED EMBODIMENTS

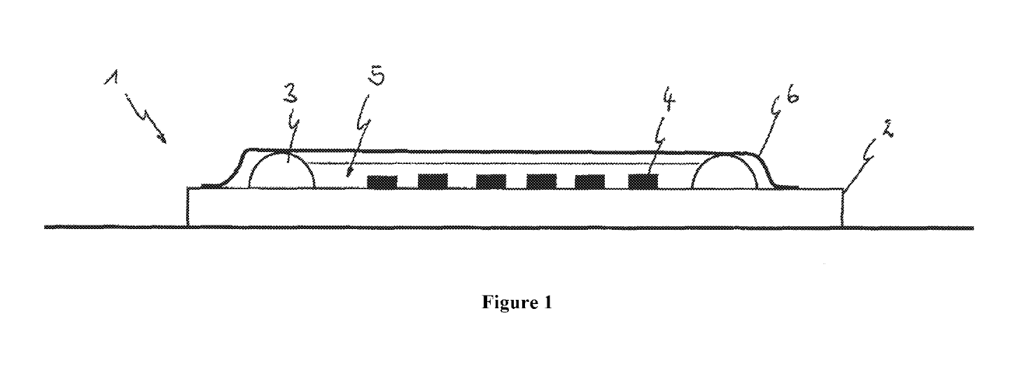

An explanation is given below of one preferred embodiment of an LED module 1 together with the methods particularly preferred in each case for producing such an LED module 1 with reference to FIGS. 1 to 3.

A first step involves providing a module plate 2 with a (at least one) dam 3, which preferably demarcates a substantially circular light field. A multiplicity of LED chips 4 are arranged within the light field.

For the sake of better clarity, a reference sign is assigned by way of example only to one LED chip in each case in the figures. The LED chips 4 here are particularly preferably arranged in rows and columns in the light field, such that a substantially homogeneous distribution of LED chips 4 on the light field can be achieved. As an alternative to the circular dam 3 shown here there is also the possibility of providing a plurality of interconnected or respectively separately arranged dams on the module plate 2.

Preferably, the dam 3 has a width as seen in plan view of between 50 gm and 2 mm. The dam 3 here can either be formed directly on the module plate 2 or firstly be produced as a separate component that is subsequently connected to the module plate 2.

Depending on the application, blue-luminous LED chips, red-luminous LED chips, green-luminous LED chips, yellow-luminous LED chips, LED chips that are luminous in the UV range, or a mixture thereof can be used as LED chips 4.

In a further step, a flowable potting compound 5 is introduced into the light field (or into the light fields), wherein the potting compound 5 is admixed with phosphor particles (distributed therein as homogeneously as possible). If a plurality of light fields are provided, different potting compounds having different phosphor particles or different phosphor particle mixtures can also be used, of course. The liquid or flowable potting compound 5, preferably a silicone- and/or epoxy-based potting compound, here is preferably applied by means of a dispensing method. After the filling of the light field with the flowable potting compound 5, the phosphor particles mixed into the latter begin to sink within the potting compound 5 on account of the gravitational force and deposit at and around the LED chips 4.

As already explained above, the phosphor particles are positively charged during the mixing process in the potting compound, such that they can be deflected during the sinking in the potting compound by an electric field which can build up between the electrodes of the LED chips on account of the photoelectric effect. This can result in a certain segregation effect that can lead to an inhomogeneous distribution of the phosphor particles and thus to an inhomogeneous light emission of the LED module.

FIGS. 1 to 4 then show particularly preferred, different solutions that can reduce or prevent such a segregation effect.

A solution shown in FIG. 1 can be provided by at least the LED chips 4 being darkened during the sinking process, such that no or only a considerably reduced photoelectric effect occurs, such that no or a considerably reduced deflection of the positively charged phosphor particles occurs. Such darkening is hence a form of indirectly applying a predetermined potential to the LED chips 4. Such darkening can be carried out for example by a film 6 (preferably a dark or black film) arranged on the LED module 1. The film 6 here is arranged on the LED module 1 after the filling with the potting compound 5 in such a way that at least the LED chips 4 are covered and thereby darkened. The film 6 here can be embodied in such a way that light can no longer reach the LED chips 4 or the latter can only be reached by light that lies outside the (main) absorption spectrum of the LED chips 4, such that a photoelectric effect no longer occurs or it can be considerably reduced.

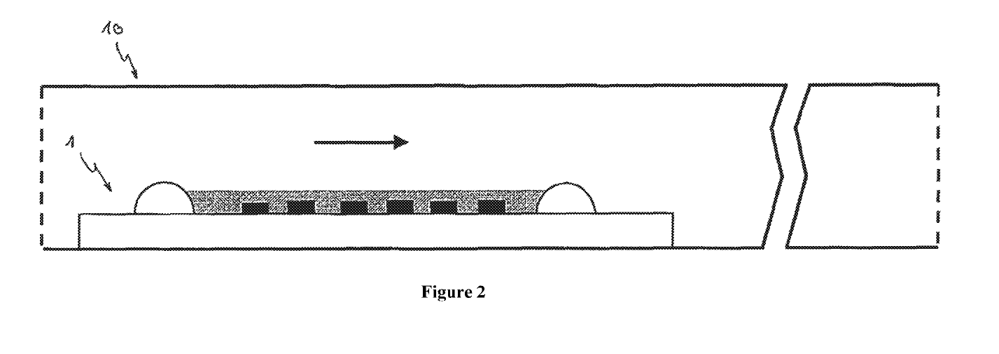

As shown in FIG. 2, there is furthermore the possibility of arranging the LED module 1 within a darkened environment, for example within a darkened channel 10, at least while the phosphor particles sink in the potting compound 5. Instead of such a darkened channel 10, it is also possible to carry out production or the individual steps of production in a correspondingly darkened environment or to effect illumination only with light that emits light that lies outside the (main) absorption spectrum of the LED chips 4, such that a photoelectric effect no longer occurs or it can be considerably reduced. Such production in a correspondingly darkened environment is hence a form of indirectly applying a predetermined potential to the LED chips 4.

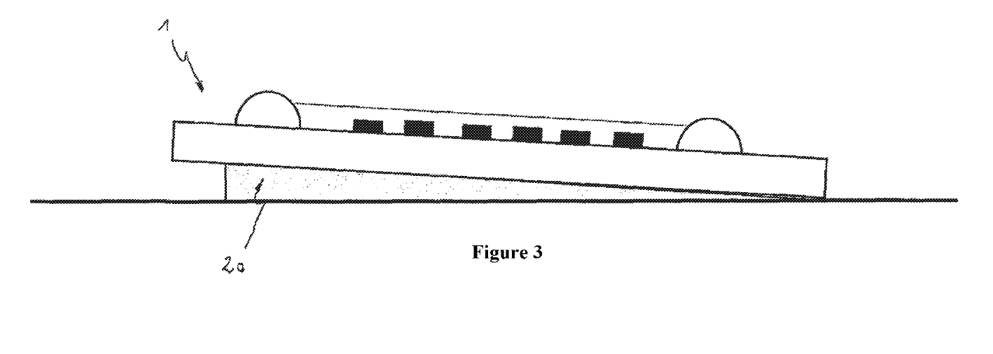

FIG. 3 shows a further possibility for reducing the segregation effect mentioned. As can readily be discerned in FIG. 3, in this solution the LED module 1 is mounted obliquely with respect to the horizontal at least while the phosphor particles sink in the potting compound 5, such that the deflection of the phosphor particles that occurs can be compensated for as far as possible by the gravitational force and the phosphor particles can once again sink as rectilinearly as possible in the potting compound 5 as well. Depending on the charge of the phosphor particles and depending on the magnitude of the electrical potential between the electrodes of the LED chip, the angle of inclination of the LED module during the soaking of the phosphor particles should be adapted accordingly in order to enable a substantially linear sinking of the phosphor particles.

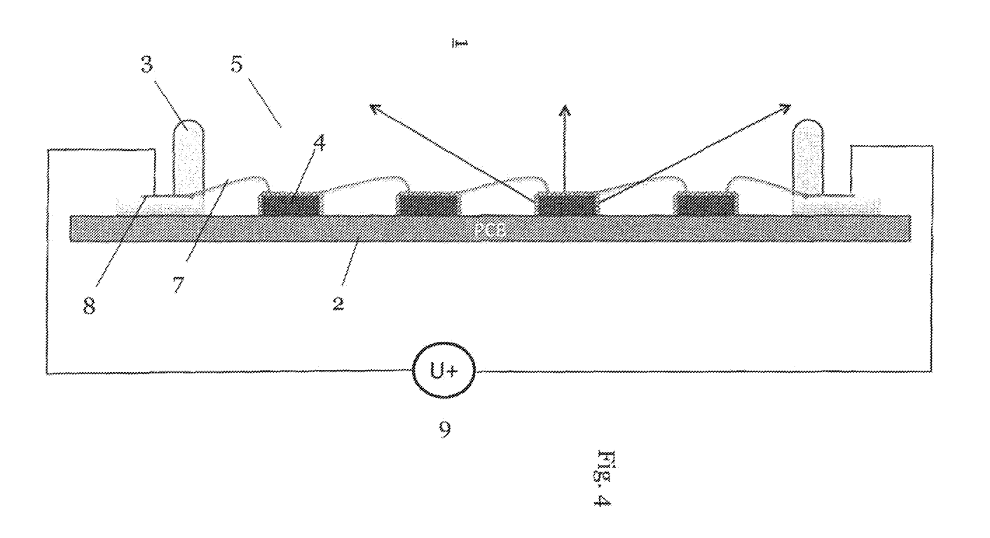

The LED module 1 in FIG. 4 contains one or—as shown—a plurality of LED chips 4 that can be operated for light emission. By way of example, the LED chips 4 can be designed to emit blue light during operation. However, it is also possible to install LED chips 4 of different types in the LED module 1, which emit light of different colors or wavelengths. The LED chips 4 are applied on a carrier 2, for example a circuit board such as, for instance, a PCB. Preferably, a surface of the carrier 2 on which the LED chips 4 are applied is reflective. Preferably, the LED chips 4 in the LED module 1 are contacted in series by means of bond wires 7. Each LED chip 4 here is preferably connected using at least two bond wires 7. Via the bond wires 7, the LED chips 4 can be supplied with voltage and driven for the operation of the LED module 1. During the method 100 for producing the LED module 1, it is possible to charge the LED chips with the second polarity via the bond wires 7.

In the LED module 1, the LED chips 4 are arranged in particular within a dam 3. The dam 3 here can at least partly enclose the LED chips 4 as indicated in FIG. 3, for example in a ring-shaped fashion. For the operation of the LED module 1, at least two bond wires 7 are led outside the dam 3 to at least two bond pads 8. The bond pads 8 can furthermore be directly or indirectly connected to an operating voltage source.

Within the dam 3, the LED chips 4 are embedded into a matrix material, for example a silicone matrix. The LED module 1 is thus preferably produced by means of the “dam and fill” technique. The matrix material is preferably fully transparent to the light from the LED chips 4 and protects the LED chips 4 and the coatings thereof against external influences. Furthermore, color conversion particles 5 are also provided in the matrix material. The color conversion particles 5 here are deposited in each case with uniform thickness in particular on the surfaces facing away from the carrier 2 and on the side surfaces of the LED chips 4. This is achievable by the above-described method 100 according to the invention.

The color conversion particles 5 can be for example phosphors that convert the light of the LED chips 4 at least partly in its wavelength. If the LED chips 4 emit in the blue spectral range, for example, then overall white light can be generated by the LED module 1 for example by virtue of a color conversion material that emits in the yellow spectral range for the color conversion particles 5. Different colors and color mixtures of the light emitted by the LED module 1 can be generated by means of a corresponding choice of the color conversion material of the color conversion particles 5 and the type (emission wavelength) of the LED chips 4.

It can furthermore be seen in FIG. 3 that in the LED module 1 between the LED chips 4 no color conversion particles 5 are deposited on the surface of the carrier 2. The color conversion particles 5 are deposited in particular only on and laterally at the LED chips 4. As a result, the carrier surface between the LED chips 4 is exposed and is preferably designed to be reflective at least there, in order to support and optimize the coupling-out of light from the LED module 1. As is indicated by the arrows in FIG. 3, during the operation of the LED module 1 light emerges from each of the LED chips 4 and then, independently of its emission angle, passes through a layer of color conversion particles 5 that is of approximately identical thickness. This ensures that a very uniform, in particular identically colored light is emitted by each LED chip 4. Consequently, overall the uniformity of the light emitted by the LED module 1 during operation, in particular the color homogeneity of said light over the emission angle, is significantly improved.

It is also pointed out in addition that color conversion particles 5 can also deposit on the bond wires 7 that connect the LED chips 4 of the LED module 1 to one another. The bond wires 7 are in part even enveloped by color conversion particles 5.

In order to produce the color conversion coating of the LED chips 4, firstly the color conversion particles 5, preferably mixed in and with the matrix material, are apportioned between the dam 3 and over the LED chips 4. A viscosity of the matrix material is preferably chosen in such a way that the color conversion particles 5 can spread in the matrix material and migrate therein.

Conventionally, a settling process of the color conversion particles 5 would then begin, in which the color conversion particles 5 would deposit on the surfaces of the LED chips 4 and/or of the carrier 2 in a manner driven purely by the gravitational force before the matrix material is cured.

According to the invention, however, this settling process is supported or at least influenced by applying a predetermined potential to the LED chips 4. Applying a predetermined potential to the LED chips can be carried out by applying a corresponding voltage such as a DC or AC voltage, for example, to the LED chips 1. That means that at least one defined electric field arises between the LED chips 4 and the color conversion particles 5.

In addition, a predetermined potential can also be applied to the carrier 2. This can be carried out by applying a voltage to the carrier 2. As a result, by way of example, sinking color conversion particles 5 can be prevented from depositing on the top side of the carrier 2. In particular, the color conversion particles 5 are repelled by the top side of the carrier, such that the coating of the side surfaces of the LED chips 4 is supported further and what is primarily achieved is that the layer on the top side and on the side surfaces of the LED chips 4 is of uniform thickness. This additionally fosters a situation in which the color conversion particles 5 are wholly or largely dispelled from the top side of the carrier 2 between the LED chips 4 and between the outermost LED chips 4 and the dam 3. Said color conversion particles 5 are then forced toward the side surfaces of the LED chips 4 and deposit there on account of the applied voltage. As a result, the interspaces on the top side of the carrier remain largely free of color conversion particles 5 and preferably form reflective areas.

By way of example, the predetermined potential can be applied by voltage U+ generated by a voltage source 9. A voltage U+ generated by preferably the same voltage source 9 is applied to the LED chips 4 via the bond pads 8 and the bond wires 7. On account of the voltage U+, an electric field can build up on the top side of the LED chips 4, said electric field constraining the charged color conversion particles 5 toward the LED chips 4.

As a result, the settling process of the color conversion particles 5 can be accelerated and the color conversion particles 5 deposit on the top sides and the side surfaces of the LED chips 4.

The voltage U+ at the LED chips 4 can preferably be between 20-100 V, more preferably between 40-80 V, even more preferably 60 V.

By way of example, the predetermined potential can be applied by short-circuiting the bond pads 8 and thus the LED chips 4. What is achieved by short-circuiting the LED chips 4 via the bond pads 8 and the bond wires 7 is that the same potential is present at all the LED chips 4 and also at all parts and electrodes of the LED chips 4. What can be achieved on account of the short-circuiting of the LED chips 4 is that a uniform electric field can build up on the top side of the LED chips 4, and the charged color conversion particles 5 sink uniformly toward the LED chips 4. As a result, the settling process of the color conversion particles 5 can be influenced and the color conversion particles 5 deposit on the top sides and the side surfaces of the LED chips 4. Additionally, or alternatively, the electrical terminals of the at least one LED chip can be grounded. By way of example, the bond pads 8 can be connected to a ground terminal, for example to a reference potential terminal.

The predetermined potential can also be formed by a changing applied voltage, whereby applied voltages U+ of different magnitudes over time are applied. That means that the electric fields at the LED chips 4 can be set in a targeted manner in each case, preferably even as variable over time. As a result, a quantity and/or a form of deposition of the color conversion particles on the top sides and/or side surfaces of the LED chips 4 can be set with precision, in particular even slightly inhomogeneously over the course of the top side and/or of the side surfaces of the LED chips 1. As a result, the color homogeneity of the finished produced LED module 1 can again be improved. In particular, by means of suitable setting of the voltages U+, it is also possible to perfect the color homogeneity over the emission angle. Here a voltage could moreover also be applied directly to the carrier 2 in order to charge it.

The invention also relates to a method for producing an LED module 1, said method comprising at least the following steps:

providing at least one LED chip 4 on a carrier material 2,

dispensing a non-cured (flowable/liquid) potting compound 5 above the LED chip 4,

wherein the potting compound 5 contains at least one type of phosphor particles and preferably a matrix material,

wherein a predetermined potential is applied to at least one LED chip 4 directly or indirectly during the dispensing process.

By means of the further proposals for reducing or for avoiding such segregation as mentioned above and in the particularly preferred exemplary embodiments, LED modules having a more homogeneous phosphor particle distribution in comparison with the known LED modules can be provided, such that a more homogeneous light emission overall can be provided as a result. In particular, the present invention is not restricted to LED modules produced by a “dam-and-fill” method, but rather relates generally to all LED modules in which a potting compound is applied in which phosphor particles can still move within the matrix material (for example on an epoxy or silicone basis).

The present invention is not restricted to the exemplary embodiments above, as long as it is encompassed by the subject matter of the following claims Furthermore, the exemplary embodiments above can be combined with and among one another in any desired way. In particular, the present invention is not restricted to the case where all LED chips arranged in the light field must necessarily be provided with phosphor.

1. An LED module produced by a method comprising:
providing at least one LED chip (4) on a carrier material (2),
dispensing a non-cured liquid potting compound (5) above the LED chip (4),
wherein the potting compound (5) contains at least one type of phosphor particles and preferably a matrix material,
wherein a predetermined potential is applied to at least one LED chip (4) directly or indirectly during the dispensing of the potting compound (5).

2. The LED module (1) produced according to the method as claimed in claim 1,
wherein applying the predetermined potential is carried out by short-circuiting electrical terminals of the at least one LED chip (4) while the phosphor particles sink in the liquid potting compound (5).

3. The LED module (1) produced according to the method as claimed in claim 1,
wherein applying the predetermined potential is carried out by applying an AC voltage to electrical terminals of the at least one LED chip (4) while the phosphor particles sink in the liquid potting compound (5), wherein the voltage and the frequency of the AC voltage are selected such that the phosphor particles sink substantially linearly in the liquid potting compound (5).

4. The LED module (1) produced according to a method as claimed in claim 1,
wherein applying the predetermined potential is carried out by applying a DC voltage to electrical terminals of the at least one LED chip (4) while the phosphor particles sink in the liquid potting compound (5), in order to deflect the phosphor particles at least partly in a direction of the LED chips (4).

5. The LED module (1) produced according to the method as claimed in claim 1,
wherein applying the predetermined potential is carried out by arranging the LED module (1) within a magnetic field while the phosphor particles sink in the liquid potting compound (5), wherein alignment and strength of the magnetic field are selected such that the phosphor particles sink substantially linearly in the liquid potting compound (5).

6. The LED module (1) according to the method as claimed in claim 1,
wherein, during the dispensing process, at least the region of the potting compound (5) is shielded from light in a region of an excitation spectrum of the phosphor particles and a predetermined potential is applied indirectly to at least one LED chip (4).

7. An LED module (1) produced according to a method comprising:
providing a module plate (2), with at least one dam (3) which delimits at least one light field, wherein at least one LED chip (4) is arranged within the light field;
dispensing a liquid potting compound (5) onto the at least one LED chip (4), wherein the potting compound (5) comprises phosphor particles;
darkening the at least one LED chip (4) in such a way that at least in the absorption spectrum of the at least one LED chip (4) no light passes to the at least one LED chip (4) at least during the sinking of the phosphor particles in the liquid potting compound (5) and a predetermined potential is applied indirectly to at least one LED chip (4).

8. The LED module (1) as claimed in claim 1 wherein the entire LED module is darkened at least during the sinking of the phosphor particles.

9. The LED module (1) as claimed in claim 1, wherein the LED module (1) is arranged in a darkened environment at least during the sinking of the phosphor particles.

10. The LED module (1) as claimed in claim 1, wherein, at least during the sinking of the phosphor particles, the LED module (1) is arranged in an environment which is illuminated by a light source that emits visible light outside the absorption spectrum of the LED chip (4).

11. The LED module (1) as claimed in claim 1, wherein the at least one LED chip (4) or the LED module (1) is covered by a film that is light-nontransmissive at least in the absorption spectrum of the at least one LED chip (4), the film being a dark or black film (6), at least during the sinking of the phosphor particles.

12. An LED module (1) produced according to a method comprising:
providing a module plate (2) with at least one dam (3) which delimits at least one light field, wherein at least one LED chip (4) is arranged within the light field;
dispensing a liquid potting compound (5) onto the at least one LED chip (4), wherein the potting compound (5) comprises phosphor particles;
wherein, at least during the sinking of the phosphor particles in the potting compound (5), the LED module (1) is arranged obliquely with respect to the horizontal in such a way that the phosphor particles sink substantially linearly in the liquid potting compound (5).

13. An LED module (1) produced according to a method comprising:
providing a module plate (2) with at least one dam (3) which delimits at least one light field, wherein at least one LED chip (4) is arranged within the light field;
dispensing a liquid potting compound (5) onto the at least one LED chip (4), wherein the potting compound (5) comprises phosphor particles;
wherein, at least during the sinking of the phosphor particles in the potting compound (5), the LED module (1) is accelerated in such a way that a distribution of the phosphor particles that is as homogeneous as possible is provided at least around the region of the at least one LED chip (4).

14. An LED module (1) produced according to a method comprising:
providing a module plate (2) with at least one dam (3) which delimits at least one light field, wherein at least one LED chip (4) is arranged within the light field;
dispensing a liquid potting compound (5) onto the at least one LED chip (4), wherein the potting compound (5) comprises phosphor particles;
wherein, after the sinking of the phosphor particles in the liquid potting compound (5), a directional flow is generated in order to provide a distribution of the phosphor particles that is as homogeneous as possible at least around the region of the at least one LED chip (4),
wherein the flow is generated in the liquid potting compound (5) by a steering device arranged in the liquid potting compound (5), in particular a microstirrer.

15. The LED module (1) produced according to a method as claimed in claim 1,
wherein, during the sinking of the phosphor particles in the liquid potting compound (5), the LED module (1) is operated at intervals by applying the predetermined potential in such a way that the potting compound (5) cures layer by layer on account of light emission.

16. An LED module (1) produced according to a method comprising:
providing a module plate (2) with at least one dam (3) which delimits at least one light field, wherein at least one LED chip (4) is arranged within the light field;
sieving phosphor particles onto the at least one light field;
dispensing a liquid potting compound (5) onto the at least one LED chip (4).

17. An LED module (1) produced according to a method comprising:
providing a module plate (2) with at least one dam (3) which delimits at least one light field, wherein at least one LED chip (4) is arranged within the light field;
applying phosphor particles onto the at least one light field by means of a spray mist coating step;
dispensing a liquid potting compound (5) onto the at least one LED chip (4).

18. The LED module (1) as claimed in claim 1, further comprising:
a module plate (2) with at least one dam (3) which delimits at least one light field, wherein at least two linearly arranged LED strings each having a plurality of series-connected LED chips (4) are provided within the light field; and wherein
the LED strings are arranged with alternating polarities in the at least one light field.

19. The LED module (1) as claimed in claim 1, further comprising:
a module plate (2) with at least one dam (3) which delimits at least one light field, wherein a plurality of LED chips (4) are provided within the light field; and wherein
the LED chips (4) are arranged in alternating polarity with respect to one another in the at least one light field.

20. The LED module (1) as claimed in claim 1, wherein the phosphor particles are from inorganic phosphor particles.

21. The LED module (1) as claimed in claim 1, wherein the liquid potting compound (5) is a silicone-based or epoxy-based or both silicone- and epoxy-based potting compound (5) and is transparent in the cured state.

22. The LED module (1) as claimed in claim 1, wherein the liquid potting compound (5) is applied by a dispensing method.

23. The LED module (1) as claimed in claim 1, wherein the dam (4) has a width as seen in plan view of between 50 μm and 2 mm.

24. A lighting device, comprising at least one LED module (1) as claimed in claim 1.

25. A method for producing an LED module (1), said method comprising:
providing at least one LED chip (4) on a carrier material (2),
dispensing a non-cured (flowable/liquid) liquid potting compound (3) above the at least one LED chip (4),
wherein the potting compound (3) contains at least one type of phosphor particles and a matrix material,
wherein a predetermined potential is applied to at least one LED chip (4) directly or indirectly during the dispensing process.
